(19) United States
(12) Patent Application Publication
(10) Pub. No.: US 2026/0040910 A1
(43) Pub. Date: Feb. 5, 2026

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventor: HUNG-TE LIN, HSINCHU COUNTY (TW)

(21) Appl. No.: 18/792,597

(22) Filed: Aug. 2, 2024

(51) Int. Cl. H01L 21/762; H01L 29/78

(52) U.S. Cl. CPC H01L 21/76237; H01L 21/76224; H10D 30/65

(57) ABSTRACT

A method of manufacturing a semiconductor device includes: performing a first etching operation to form a first trench in a semiconductor substrate; forming a doped region to on a first sidewall of the first trench; performing a second etching operation on the first trench to form a second trench in the semiconductor substrate; depositing a dielectric material in the first and second trenches to form an isolation structure, wherein the isolation structure defines a channel region of the semiconductor device from a top-view perspective; and depositing a dielectric layer on the semiconductor substrate over the doped region and the channel region.

### BACKGROUND

A high-voltage (HV) metal-oxide semiconductor (MOS) field-effect transistor (FET) or a medium voltage (MV) MOSTEFT, is a MOSFET that is generally configured as a peripheral device and has a relatively high operation voltage, e.g., in a range of tens or hundreds of volts, as compared to a low-voltage MOSFET that is generally configured as a core device in an electronic device. The HV/MV MOSFET has found many applications in power electronics, e.g., a switch-mode power supply (SMPS), a DC-DC converter, or an automotive application. An HV/MV MOSFET generally includes a relatively thick gate dielectric layer between the channel region and the gate structure of the MOSFET to withstand a medium to high operation voltage supplied from the gate structure.

### BRIEF DESCRIPTION OF THE DRAWINGS

Aspects of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIGS. 1A to 1J are cross-sectional views of intermediate stages of a method of manufacturing a semiconductor device, in accordance with some embodiments.

FIG. 2A is a schematic diagram showing an edge device effect of a semiconductor device, in accordance with some embodiments of the present disclosure.

FIG. 2B is a diagram showing a drain current versus a gate voltage for a semiconductor device, in accordance with some embodiments of the present disclosure.

FIG. 3 is a cross-sectional view of a semiconductor device, in accordance with some embodiments of the present disclosure.

FIGS. 4A and 4B show a perspective view and a top view of an oxide definition region and a gate structure of a semiconductor device, in accordance with some embodiments of the present disclosure.

FIGS. 5A and 5B show top views of a semiconductor device, in accordance with some embodiments of the present disclosure.

FIGS. 6A and 6B are enlarged cross-sectional views of a region of the semiconductor device shown in FIG. 1J, in accordance with some embodiments of the present disclosure.

FIGS. 7A and 7B are enlarged cross-sectional views of a region of the semiconductor device shown in FIG. 1J of the present disclosure.

FIG. 8A shows a cross-sectional view and a top view of a semiconductor device, in accordance with some embodiments of the present disclosure.

FIG. 8B shows a cross-sectional view and a top view of a semiconductor device, in accordance with some embodiments of the present disclosure.

FIG. 9A shows a cross-sectional view and a top view of a semiconductor device, in accordance with some embodiments of the present disclosure.

FIG. 9B shows a cross-sectional view and a top view of a semiconductor device, in accordance with some embodiments of the present disclosure.

FIG. 10 shows a schematic flow chart of a method of manufacturing a semiconductor device, in accordance with some embodiments of the present disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings. Further, like reference numerals across different figures dictate similar features, and therefore a detailed explanation of the similar feature may be provided when such features are first introduced in the disclosure, and may not be subsequently repeated.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Embodiments of the present disclosure discuss a method and a structure of a high-voltage semiconductor structure of a metal-oxide semiconductor (MOS) field-effect transistor (FET) for high-voltage (HV) or medium-voltage (MV) applications. Existing semiconductor structures in an HV/MV FET may have a gate structure disposed on a substrate, a gate dielectric layer between the substrate and the gate structure, a pair of source/drain regions, an a channel region within the substrate below the gate dielectric layer between the pair of the gate structure. A biasing voltage may be applied to the gate structure (the biasing voltage may be also referred to as the gate voltage) to attract carriers to flow in the channel region from one of the pair of source/drain regions to the other of the pair of the source/drain regions. A drain current occurs accordingly between the pair of source/drain regions through the channel region, in which the current level may be approximately proportional to the magnitude of the gate voltage. According to some embodiments, the material and the dimension, e.g., the thickness, of the gate dielectric layer may affect the relationship of the drain current and the gate voltage. For example, a thicker gate dielectric layer may require a relatively greater gate voltage to attain the same drain current level. Further, when the gate dielectric layer is getting more and more thickened, the channel region may not experience a uniform thickness of the gate dielectric layer in a central region and an edge region of the gate dielectric layer. Therefore, the drain current may not increase in proportion to the increase of the increase of the gate voltage at least at some working regions of the gate voltages. Such non-proportional relationship of the drain current and the gate voltage results from thickness reduction in an edge region of the gate dielectric layer may lead to degraded device performance.

To address the abovementioned issues, an improved semiconductor structure for an HV/MV FET is proposed to eliminate or mitigate the edge effect of the thick gate dielectric layer. A doped region with a dopant conductivity the same as that of the pair of source/drain regions is formed in a peripheral portion of the channel region on at least one side of an isolation structure defining the channel region. The doped region acts as a factor to increase the turn-on voltage required to attain the same level of drain current given the absence of the doped region. As a result, the doped region would compensate for the effect of the reduced thickness of the gate dielectric layer, and the channel region may experience a substantially uniform thickness of the gate dielectric layer across the entire channel region. The levels of the drain current and the gate voltage may be tuned to follow a substantially smooth curve without any humps. The device performance of the HV/MV FET would be maintained or even improved.

Source/drain region(s) may refer to a source or a drain, individually or collectively dependent upon the context.

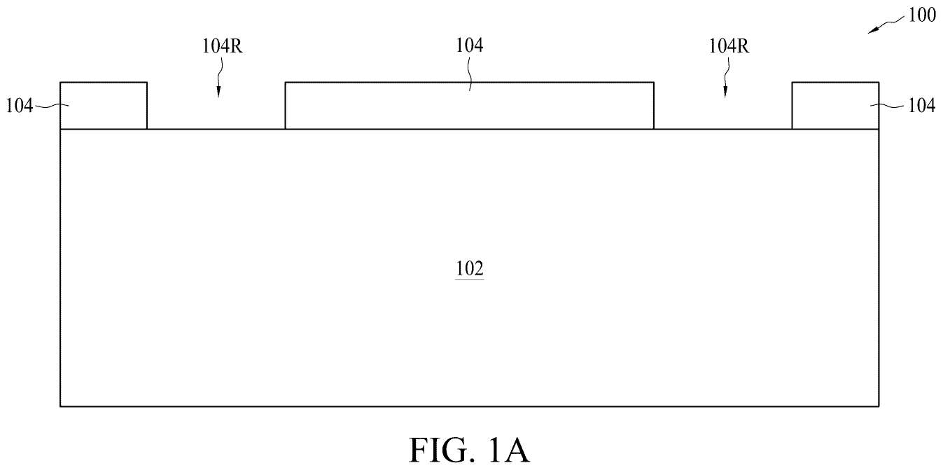

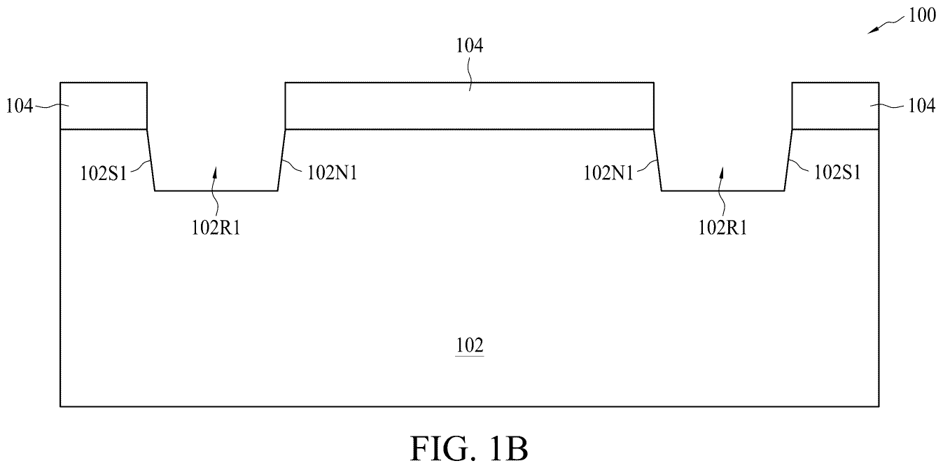

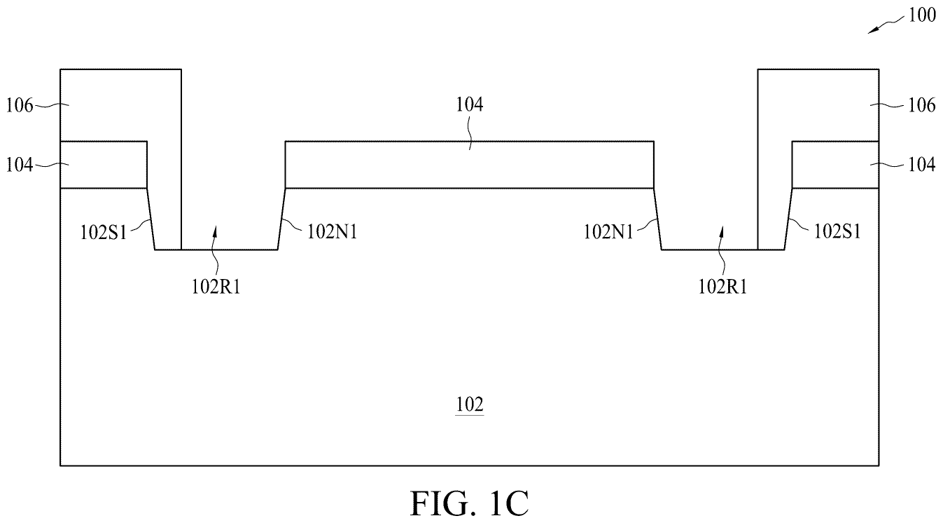

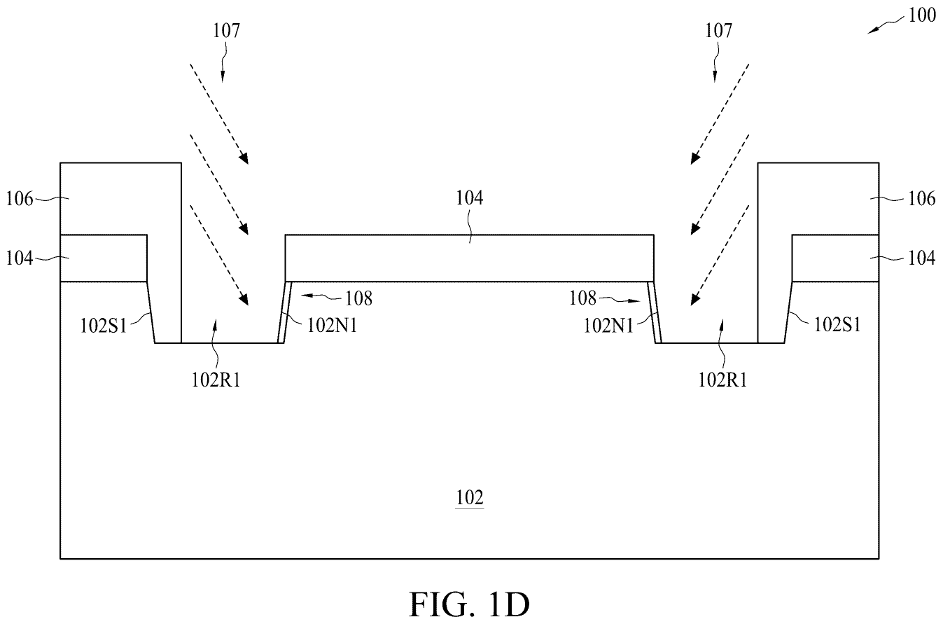

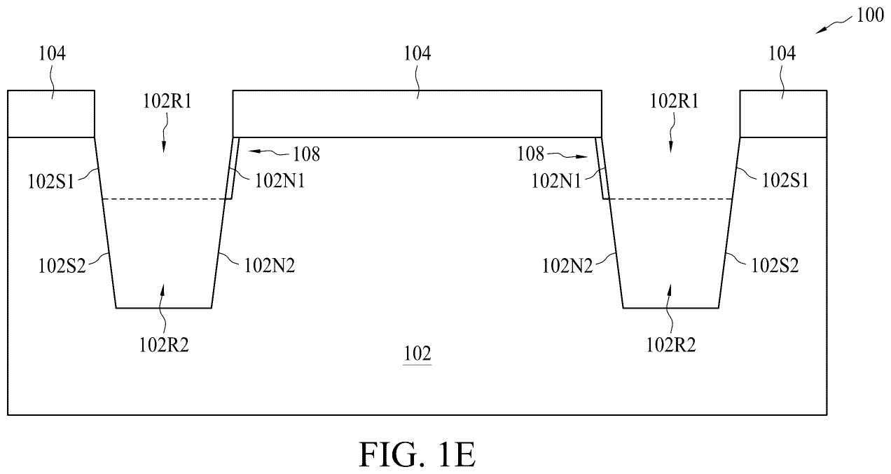

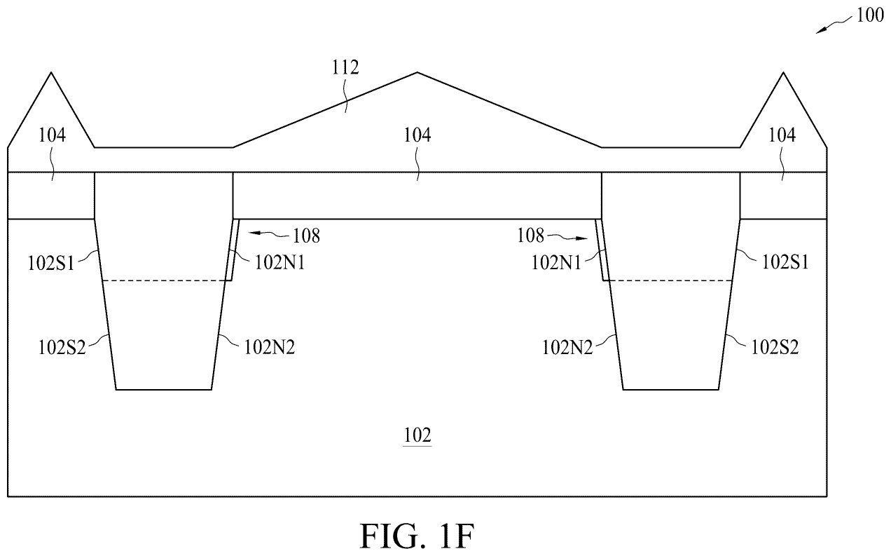

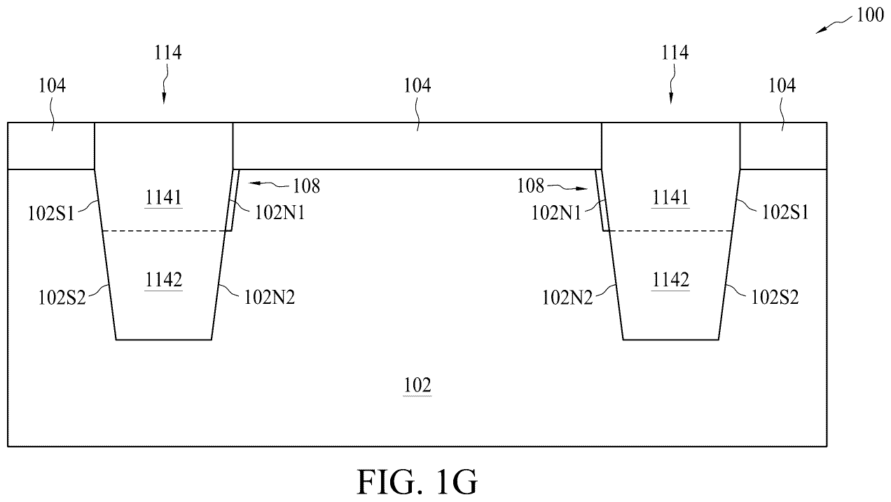

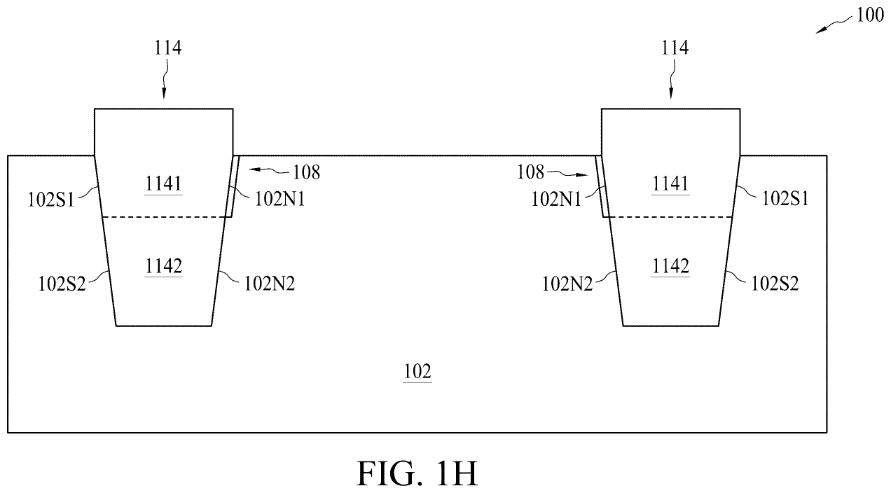

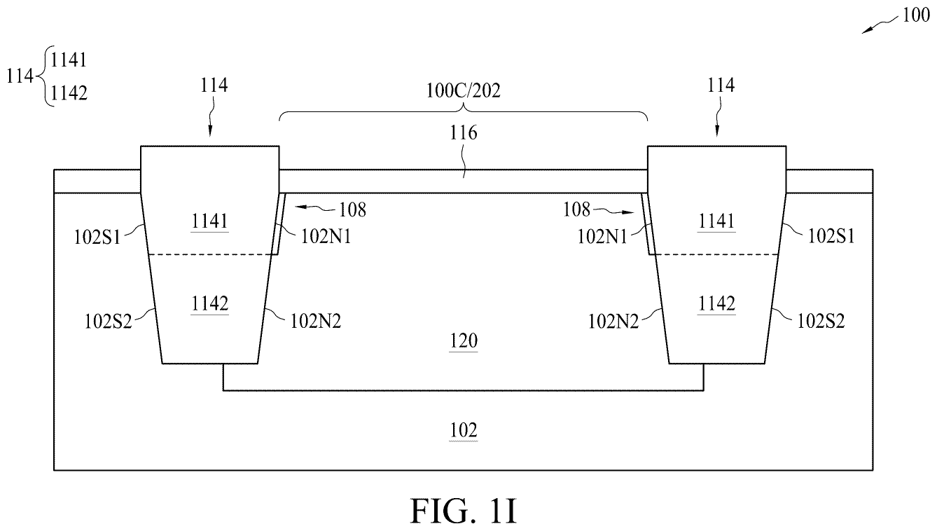

FIGS. 1A to 1J are cross-sectional views of intermediate stages of a method of manufacturing a semiconductor device 100, in accordance with some embodiments. According to some embodiments, the semiconductor device 100 is an HV/MV FET device. Referring to FIG. 1A, a semiconductor substrate 102 is provided or received. In some embodiments, the semiconductor substrate 102 includes semiconductor material such as bulk silicon. In some embodiments, the semiconductor substrate 102 includes other semiconductor materials, such as silicon germanium, silicon carbide, gallium arsenide, or the like. In the present embodiment, the semiconductor substrate 102 is a P-type semiconductive substrate (acceptor type). In some other embodiments, an N-type semiconductive substrate (donor type) 102 can be used. Alternatively, the semiconductor substrate 102 includes another elementary semiconductor, such as germanium; a compound semiconductor including gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or combinations thereof. In yet another embodiment, the semiconductor substrate 102 includes portions to form a semiconductor-on-insulator (SOI) substrate. In other alternatives, the semiconductor substrate 102 may include a doped epitaxial layer, a gradient semiconductor layer, and/or a semiconductor layer overlaying another semiconductor layer of a different type, such as a silicon layer on a silicon germanium layer.

According to some embodiments, a mask layer 104 is deposited over the semiconductor substrate 102. The mask layer 104 may be a photoresist layer. The mask layer 104 is patterned to form a plurality of trenches 104R. The plurality of trenches 104R extend through the thickness of the mask layer 104 and expose portions of the surface of the semiconductor substrate 102.

Referring to FIG. 1B, a first etching operation is performed on the semiconductor substrate 102. The first etching operation extends the trenches 104R into a thickness of the semiconductor substrate 102, and therefore a plurality of trenches 102R 1 are formed on the surface of the semiconductor substrate 102 and aligned with the corresponding trenches 104R. The first trenches 102R1 may be referred to herein as first trenches or shallow trenches 102R1. The first etching operation is performed with the patterned mask layer 104 as a pattern mask 104. According to some embodiments, the first etching operation is a dry etch, a wet etch, a combination thereof, e.g., a reactive ion etch (RIE), or the like. According to some embodiments, each of the first trenches 102R1 has an inner sidewall 102N1 and an outer sidewall 102S1, in which the inner sidewall 102N1 is closer to a well region (not shown in FIG. 1B, but illustrated in FIG. 1I and labeled as 120), a channel region 100C (not shown in FIG. 1B, but illustrated in FIG. 1I and labeled as 100C), or an oxide definition region (not shown in FIG. 1B, but illustrated in FIG. 1I and labeled as 202) of the semiconductor device 100 than the outer sidewall 102S1. According to some embodiments, the outer sidewall 102S1 may be arranged at an outer perimeter of the first trenches 102R1, while the inner sidewall 102N1 may be arranged at an inner perimeter of the first trenches 102R1. The inner sidewall 102N1 and the outer sidewall 102S1 may have substantially identical slopes, for example, as show in FIG. 1B, both the inner sidewall 102N1 and the outer sidewall 102S1 have inclined sidewalls with substantially identical slopes. The inclined sidewalls 102N1 and 102S1 or the first trenches 102R1 may taper from the surface of the semiconductor substrate 102 toward the inside of the semiconductor substrate 102.

Referring to FIG. 1C, according to some embodiments, a mask layer 106 is deposited over the semiconductor substrate 102. The mask layer 106 may include a photoresist layer, a dielectric layer (e.g., a nitride layer, an oxide layer, or the like), or other suitable materials. The mask layer 106 is patterned to cover the outer sidewall 102S1 of each of the first trenches 102R1. The inner sidewall 102N1 of each of the first trenches 102R1 is exposed through the patterned mask layer 106. According to some embodiments, the inner sidewall 102N1 of the first trench 102R1 is defined as a sidewall of the first trench 102R1 facing the channel region of the semiconductor device 100.

Referring to FIG. 1D, an ion implantation operation 107 is performed on the semiconductor device 100. The ion implantation operation 107 forms one or more doped regions 108 or implants on the inner sidewalls 102N1 of the trenches 102R1. The ion implantation operation 107 may implant ions of a conductivity same as that of the source region or drain region of the semiconductor device 100, including an N-type dopant (like phosphorus, antimony, and arsenic) or a P-type dopant (like boron, indium and aluminum). According to some embodiments, the doped regions 108 extends from the surface of the inner sidewall 102N1 to a predetermined depth of the semiconductor substrate 102. The dopant concentration and the depth of the doped regions 108 are controllable by the setup of the ion implantation operation 107.

Referring to FIG. 1E, subsequent to the ion implantation operation 107, the patterned mask layer 106 is removed or stripped. The patterned mask layer 106 may be removed by an etching operation, e.g., a wet etch, a dry etch, an RIE, or the like. A second etching operation is performed to extend the first trenches 102R1 further downward to form trenches 102R2 having inner sidewalls 102N2 and outer sidewalls 102S2. The trenches 102R2 is in communication with the first trenches 102R1, and are referred to herein as second trenches or deep trenches 102R2, and the first trenches 102R1 and the second trenches 102R2 are collectively referred to herein as the trenches 102R. The inner sidewalls 102N1 and 102N2 are collectively referred to herein as inner sidewalls 102N while the outer sidewalls 102S1 and 102S2 are collectively referred to herein as inner sidewalls 102S. The inner sidewall 102N1 extends from the inner sidewall 102N1 to the bottom surface of the second trench 102R2, and the outer sidewall 102S2 extends from the outer sidewall 102S1 to the bottom surface of the second trench 102R2.

According to some embodiments, the second etching operation for forming the second trenches 102R2 is performed using the patterned mask layer 104 as an etch mask. The second etching operation can be tuned to provide an etching rate in the vertical direction much greater than an etching rate in the horizontal direction, and therefore the inner sidewalls 102N1 and the outer sidewalls 102S1 formed by the first etching operation can be substantially keep intact during the second etching operation. The depths and areas of the doped regions 108 can be maintained after the second etching operation.

FIG. 1F shows a deposition operation of a dielectric material 112. The dielectric material is deposited over the surface of the patterned mask layer 104 and fills the trenches 102R. According to some embodiments, the dielectric material includes silicon oxide, silicon nitride, silicon oxynitride, a combination thereof, or the like. The deposition of the dielectric material 112 may include a chemical vapor deposition (CVD) or other suitable deposition methods. According to some embodiments, the deposited material 112 may include a non-flat surface over the patterned mask layer 104 and the trenches 112R due to the recessed surfaces of the trenches 112R.

Referring to FIG. 1G, a planarization operation is performed on the semiconductor device 100. The upper surfaces of the patterned mask layer 104 and the semiconductor substrate 102 are planarized during the planarization operation. The planarization operation may level the surface of the semiconductor substrate 102 with the surface of the dielectric material 112, and therefore one or more isolation structures 114 are formed in the trenches 102R. The isolation structure 114 may also be referred to as a shallow trench insulator (STI), According to some embodiments, the planarization operation includes a chemical mechanical polishing (CMP) operation, an etching operation, or the like. The inner sidewalls 102N1, 102N2 and the outer sidewalls 102S1, 102S2 of the trenches 102R are hereinafter referred to as the inner sidewalls 102N1, 102N2 and the outer sidewalls 102S1, 102S2 of the isolation structures 114. Further, each of the isolation structures 114 has an upper portion 1141 where the doped region 108 resides or which corresponds to the location of the first trench 102R1, and a lower portion 1142, below the upper portion 1141, where no doped region 108 is formed or which corresponds to the location of the second trench 102R2.

FIG. 1H illustrates a removal operation of the patterned mask layer 104. The removal operation may include an etching operation, a strip-off operation, or other suitable removal methods. According to some embodiments, the removal operation adopts an etching operation with an etchant having a high etching selectivity to the material of the patterned mask layer 104 relative to the material of the isolation structure 114. As a result, the isolation structures 114 are kept substantially intact after the removal operation. The upper surface of the semiconductor substrate 102 is exposed through the isolation structures 114. According to some embodiments, the doped region 108 has a bottom higher than a bottom surface of the isolation structure 114.

Subsequently, as shown in FIG. 1I, a dielectric layer 116 is formed over the semiconductor substrate 102. According to some embodiments, the dielectric layer 116 includes silicon oxide, or other suitable dielectric materials. The dielectric layer 116 may be formed using a thermal oxidation operation, CVD, atomic layer deposition (ALD), physical vapor deposition (PVD), or other suitable deposition operations. The dielectric layer 116 may be formed only on the surface of the semiconductor substrate 102, and the upper surfaces of the isolation structure 114 are exposed through the dielectric layer 116. The dielectric layer 116 may serve as a gate dielectric layer, on which a gate structure (not shown, but illustrated in FIG. 1J and labeled as 118) is formed, of the semiconductor device 100.

A well region 120 is formed in the semiconductor substrate 102 between the isolation structures 114. The well region may include and define a boundary of the components of the semiconductor devices 100 in the semiconductor substrate 102. The well region 120 may be formed by an ion implantation operation. The dopant conductivity, e.g., an N-type dopant or a P-type dopant, is determined according to a conductivity type of the semiconductor device 100. The dopant concentration and depth of the well region 120 can be tuned according to applications. According to some embodiments, the well region 120 has a bottom surface below the bottom surface of the isolation structure 114. The inner sidewalls 102N1, 102N2 of the isolation structure 114 can also referred to as the sidewalls 102N1, 102N2 of the well region 120. Further, a pair of source/drain regions (not separately shown) of the semiconductor device 100 are formed within the well region 120 in a subsequent step. Such source/drain regions are formed on two sides of the well region 120 in a direction traversing the paper of FIG. 1G, e.g., in a direction substantially perpendicular to the horizontal direction of FIG. 1G. The channel region 100C is thus formed between the pair of source/drain regions, and a drain current flows in the channel region 100C between the source/drain regions. Additionally, the isolation structures 114 define at least part of a boundary of a channel region 100C or the OD region 202 of the semiconductor device 100, in which the drain current flows in a direction traversing the paper of FIG. 1G between the isolation structures 114.

According to some embodiments, the order of the forming the well region 120 and forming the dielectric layer 116 is exchangeable. Further, according to some embodiments, one or more cleaning operations are performed subsequent to the formation of the planarization operation as shown in FIG. 1G or the removal operation for the patterned mask layer 104 as shown in FIG. 1H. These clean operation may introduce some etchants to clear contaminants, foreign particles, debris, undesired oxidized layers, or the like.

Referring to FIG. 1J, a gate structure 118 is formed over the channel region 100C. The gate structure 118 may be formed by deposition and patterning operations. The patterning operation may include a lithography operation and a subsequent etching operation. According to some embodiments, although not explicitly illustrated, the gate structure 118 may include a multilayer structure. The gate structure 118 can be a polysilicon gate structure or a metal gate structure. The gate structure 118 may also include one or more mask layers (not shown) on a top portion of the gate structure 118. According to some embodiments, the gate structure 118 at least partially overlaps the doped region 108 from a top-view perspective. The gate structure 118 may cover or overlap an entirety of the doped region 108.

One or more features of the semiconductor device 100 are formed in operations subsequent to the step shown in FIG. 1J, and are omitted for brevity. These features may include, but not limited to, gate spacers, source/drain regions, lightly-doped drain (LDD) regions, an interlayer dielectric (ILD) layer, conductive vias or contacts, and an interconnect structure including metal lines layers and metal via layers for interconnecting the features of the semiconductor device 100 or electrically connecting features of the semiconductor device 100 to upper devices.

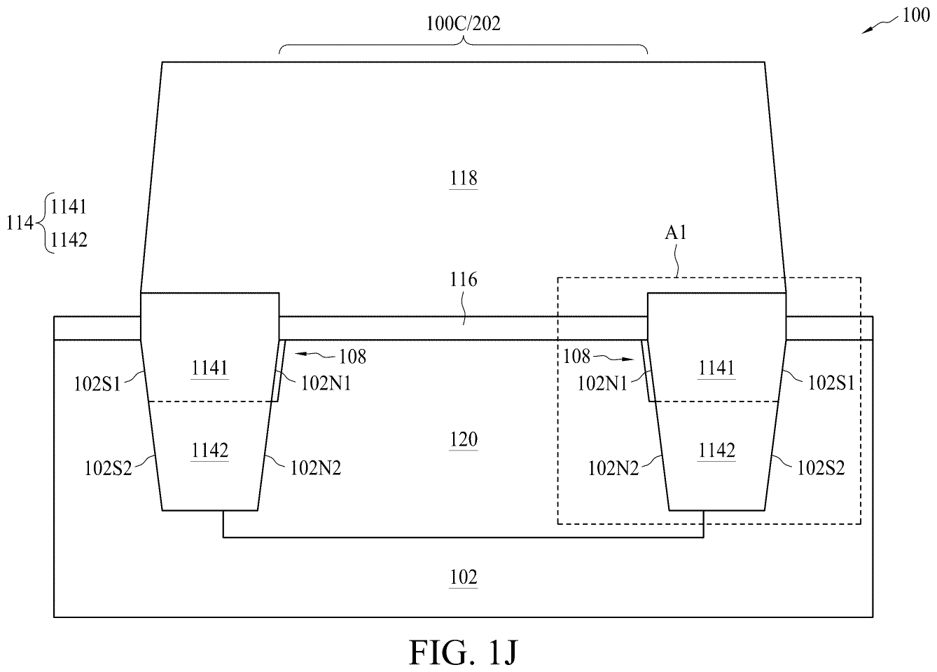

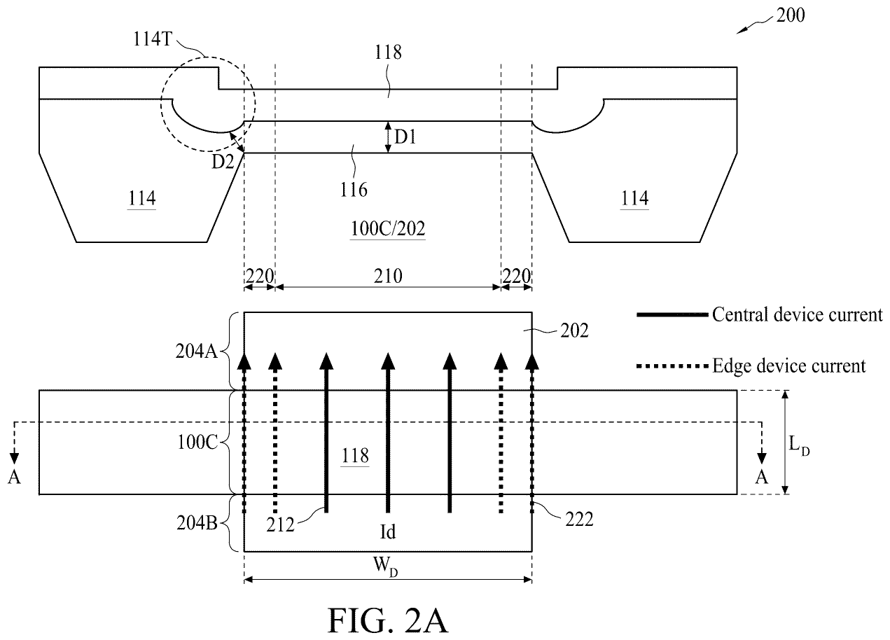

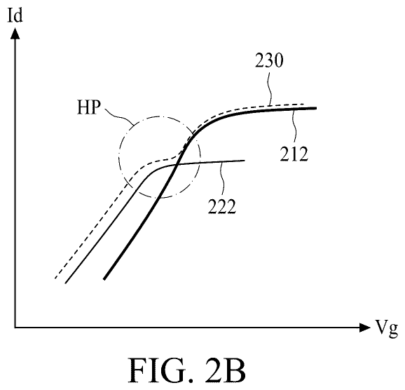

FIG. 2A is a schematic diagram showing an edge device effect of a semiconductor device 200, in accordance with some embodiments of the present disclosure. The semiconductor device 200 is similar to the semiconductor device 100 in many aspects, and details of these similar features are not repeated for brevity. Referring to FIG. 2A, a plain view and a cross-sectional view of the semiconductor device 200 are shown in a lower subfigure and an upper subfigure of FIG. 2A, where the cross-sectional view is taken from a sectional line AA in the plain view. In the subfigure of the plain view, the semiconductor device 200 includes a gate structure 118 and an oxide definition (OD) region 202 crossing each other. The OD region 202 may be a region including the pair of source/drain regions 204A and 204B the channel region 100C, in which the channel region 100C arranged between the pair of source/drain regions 204A, 204B. The channel region 10C has a length L_{D} and a width W_{D}, where the length L_{D} is a dimension measured between the source/drain regions 204A and 204B, and the width W_{D} is measured between the two adjacent isolation structures 114 at the upper surface of the semiconductor substrate 102. The length L_{D} and the width W_{D} may also referred to as the “device length” and “device width,” respectively, of the semiconductor device 200. The device width W_{D} may also be equivalent to the width of the OD region 202. The device length L_{D} may be equivalent to the width of the gate structure 118 from a top-view perspective. According to some embodiments, the length L_{D} is in a range between about 0.6 μm and about 1.2 μm, such as 0.9 μm. According to some embodiments, the width W_{D} is in a range between about 4 μm and about 6 μm, such as 5 μm. The OD region 202 may be equivalent to the well region 120 shown in FIG. 1J, or can be only part of the well region 120 and arranged within the well region 120. According to some embodiments, the OD region 202 matches the well region 120 at the upper surface of the semiconductor substrate 102.

During operation, the gate structure 118 receives a biasing voltage Vg and causes the drain current Id to flow in the channel region 100C from the source/drain region 204B to the source/drain region 204A. FIG. 2A shows a plurality of arrows on the channel region 100C to indicate the flow of the drain current. Referring to the cross-sectional view in FIG. 2A, the magnitude of the drain current is crucial to the success of operation for the semiconductor device 100 or 200, and the threshold voltage V_{T} for turning on the drain current also plays an important role in the performance of the drain current Id. According to some embodiments, the threshold voltage V_{T} is determined by several factors, such as the dielectric constant and the thickness of the dielectric layer 116, the dopant concentration of the source/drain regions 204A, 204B, the magnitude of the gate voltage Vg, and some others. For example, the thickness uniformity of the dielectric layer 116 may affect the distribution and slope of the drain current Id across a full operation range of the gate voltage Vg.

Referring to the cross-sectional views of FIG. 1J and FIG. 2A, it can been seen that the isolation structures 114 are kept substantially intact in the semiconductor device 100 shown in FIG. 1J, while the isolation structures 114 shown in FIG. 2A have a top corner □ 114T missing. Such missing top corner □ 114T may be inevitably etched or removed during one or more subsequent cleaning methods, and the locations of these damaged corners 114T may be replaced with the material of the gate structure 118 during the formation of the gate structure 118. As a result, as shown in the cross-sectional view of FIG. 2A, the effective thickness of the dielectric layer 116 may not be uniform across the central region and the edge region of the dielectric layer 116. For example, the dielectric layer 116 has a first thickness D1 around a central region and a second thickness D2 around an edge region, in which the second thickness D2 is less than the first thickness D1 by a noticeable difference. According to some embodiments, a thickness ratio D2/D1 is between about 0.05 and about 0.25. Such thickness difference may become more pronounced when the dielectric layer 116 is deposited to a relatively high thickness, e.g., in a range greater than 100 Angstrom (Å) for HV/MV applications. As a result, the thickness difference of the dielectric layer 116 between the central region and the edge region causes the channel region 100C to be partition into two parts for two component devices, e.g., a central device 210 and one or more edge devices 220 arranged in a central region and an edge region, respectively, of the channel region 100C. The drain current Id may exhibit two types of currents, referred to as the “central device current 212” and the “edge device current 222,” respectively, which correspond to the central device 210 and the edge device 220, respectively, as illustrated in FIG. 2A.

FIG. 2B is a diagram showing the drain current Id versus the gate voltage Vg for the semiconductor device 200, in accordance with some embodiments of the present disclosure. FIG. 2B illustrates the central device current 212 for the central device, the edge device current 222 for the edge device, and a total current 230 being a summation of the central device current 212 and the edge device current 222. The semiconductor device 200 exhibits the total current 230 against the gate voltage Vg as the performance of the representative drain current Id for the semiconductor device 200. As can be seen in FIG. 2B, since the edge device current 212 experiences a dielectric layer 116 with a less thickness, it would lead to a smaller threshold voltage V_{T}, and thus the turn-on voltage of the edge device would be less than that of the central device. Further, the saturation current of the edge device current 222 would also become less than that of the central device current. As a result, the total current 230 exhibits a curve that as the drain current Id increases with the increase of the gate voltage, the drain current Id experiences double humps HP along with the increase of the gate voltage Vg. Such humps would cause the drain current Id to lose the property of curve smoothness as compared to the central device current alone, in which no edge device current is present. Therefore, the “edge device effect” occurs in the semiconductor device 200 for an HV/MV electronic device application.

To mitigate or eliminate the edge device effect, the most effective way is to add some feature to or modify the features of the semiconductor device 200 for compensating for the edge device effect. In other words, such added or modified feature is devised to compensate for the reduced thickness D1-D2 of the dielectric layer 116 at the edge regions of the dielectric layer 116. Referring to FIG. 1D and FIG. 1J, the doped region 108 formed on the inner sidewalls 102N1 of the first trenches 102R1 or a sidewall of the well region 120 or the OD region 202 is configured to help increase the threshold voltage V_{T} of the edge device 220 shown in the cross-sectional view of FIG. 2A. The doped region 108 is substantially at least includes a portion aligned with the edge region. Further, the depth, thickness, dimensions, and the dopant concentration of the doped regions 108 can be tuned to compensate for the edge device effect such that the modified edge device 220 can include the edge device current 222 to exhibit in a substantially identical curve performance to the central device current 212 of the central device 210, as illustrated in FIG. 2B. The doped region 108 is therefore also referred to as a hump-suppressing structure. The edge device effect can be effectively mitigated or eliminated, and the device performance, for example in the turn-on stage, can be maintained or improved.

According to some embodiments, in order to provide an additional hump-suppressing effect, the doped region 108 has a dopant conductivity (e.g., P-type or N-type) same as that of the well region 120 or the channel region 100C and includes a dopant concentration greater than that of the well region 120 or the channel region 100C. For example, the dopant concentration of the doped region 108 is in a range between about 3×10¹² and about 1×10¹⁵ atoms per square centimeter. According to some embodiments, a dopant concentration ratio between the doped region 108 and the well region 120 or the channel region 100C is between about 10 and about 500.

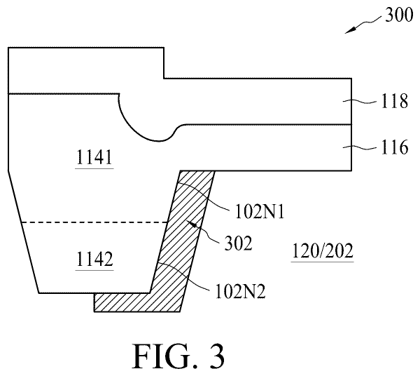

FIG. 3 is a cross-sectional view of a semiconductor device 300, in accordance with some embodiments of the present disclosure. FIG. 3 only shows part of the semiconductor device 300, e.g., a doped region 302, the isolation structure 114 including the upper portion 1141 and the lower portion 1142, the dielectric layer 116, and the well region 120. Most of the features of the semiconductor device 300 is similar to those of the semiconductor device 100, and details of these similar features are not repeated for brevity. Further, the doped region 302 serves similar functions to the doped regions 108, i.e., for compensating for the edge device effect due to the non-uniform thickness of the dielectric layer 116 at the central region and the edge region. The main difference between the semiconductor device 300 and the semiconductor device 100 is that the doped region 302 extends from the sidewall 102N1 facing the upper portion 1141 downward to the sidewall 102N2 facing the lower portion 1142. The doped region 108 may extend to a depth of the semiconductor substrate 102 by a range between about 5 nm and about 1 μm. According to some embodiments, the isolation structure 114 has a depth of about 0.3 μm measured from the surface of the semiconductor substrate 102 or the well region 120. A depth ratio of the doped region 108 to the isolation structure 114 may be in a range between about 1% to about 50%. According to some other embodiments, the doped region 302 covers an entire sidewall 102N (including the sidewall 102N1 and the sidewall 102N2) of the well region 120 or the OD region 202 (shown in FIG. 2A). According to some embodiments, the doped region 302 covers a bottom corner of the isolation structure 114. The doped region 302 may extend below the bottom surface of the isolation structure 114.

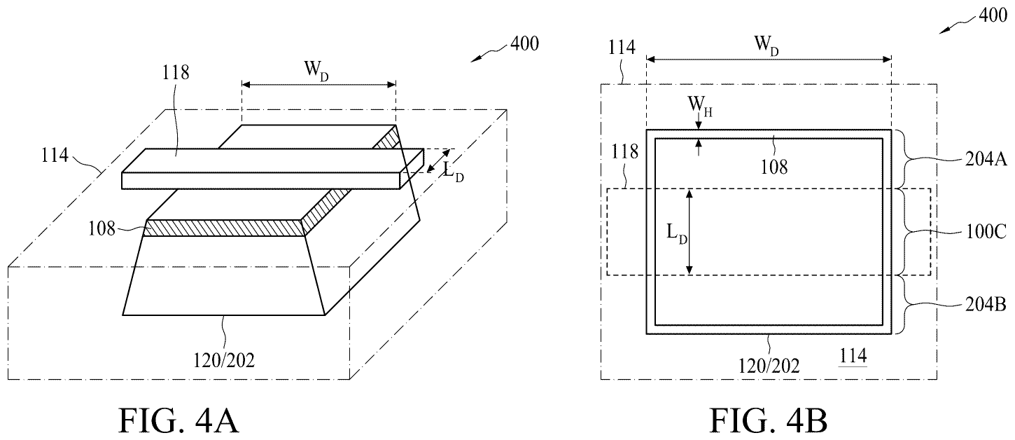

FIGS. 4A and 4B show a perspective view and a top view of the OD region 202 and the gate structure 118 of a semiconductor device 400, in accordance with some embodiments of the present disclosure. The semiconductor device 400 is similar to the semiconductor device 100, and details of these similar features are omitted for brevity. FIG. 4A and FIG. 4B only shows the OD region 202 (or equivalently the well region 120), the isolation structures 114, the gate structure 118 and the doped region 108 to illustrate the locations of the doped region 108 in some other embodiments. As seen in FIG. 4A and FIG. 4B, the isolation structure 114 laterally surrounds and defines the well region 120 or the OD region 202 from a top-view perspective, and the doped region 108 is formed on a perimeter of the OD region 202 near a surface of the OD region 202 or the semiconductor substrate 102. That means the doped region 108 covers the entire perimeter of the OD region 202 from a top-view perspective. According to some embodiments, the doped region 108 overlaps the source/drain region 204A or 204B at an outer perimeter of the source/drain region 204A or 204B not covered by the gate structure 118. According to some embodiments, the doped region 108 covers the sidewalls of the channel region 100C on the two sides facing the adjacent isolation structures 114 (see also FIG. 1J). According to some embodiments, the doped region 108 only covers the sidewalls of the OD region 202 within the range of the channel region 100C but leaves the dopant concentration of sidewalls of the OD region 202 on the source/drain regions 204A, 204B free of the doped region 108. The area of the sidewalls where the doped region 108 is implanted can be determined by the scope of the first trench 102R1. For those sidewalls of the OD region 202 exposed in the forming operation of the first trench 102R1, these sidewalls can be implanted with the dopants of the doped region 108, followed by the forming of the second trench 102R2 (see FIGS. 1B to IF). For example, if the doped region 108 is to be formed on the entire perimeter of the sidewalls of the OD region 202, the first trench 102R1 shown in FIG. 1B can be a ring shaped trench surrounding the OD region 202. According to some embodiments, the performance of the doped region 108 is better when it is formed within the scope of the channel region 100C than it is formed in other locations of the OD region 202. The range of the doped region 108 can be determined according to applications and considerations of process compatibility with other operations for forming the semiconductor device 400. According to some embodiments, the doped region 108 includes a width W_{H} from a top-view perspective. The width WH may be in range between about 5 nm and between 0.1 μm. A doped region 108 including a width less than about 5 nm may not provide a sufficient hump-suppressing effect, and a doped region 108 including a width greater than about 0.1 μm may adversely impact the characteristics of the central device current or other electrical properties of the semiconductor device 100.

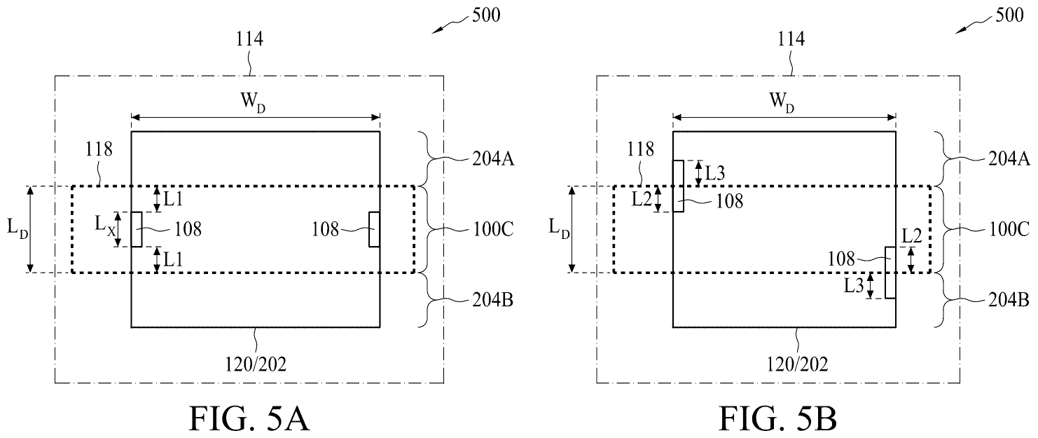

FIGS. 5A and 5B show top views of a semiconductor device 500, in accordance with some embodiments of the present disclosure. The semiconductor device 500 is similar to the semiconductor device 100 or 400, and details of these similar features are omitted for brevity. FIG. 5A and FIG. 5B only shows the OD region 202 (or equivalently the well region 120), the gate structure 118 and the doped region 108 to illustrate different arrangements of the doped region 108 in some other embodiments.

Referring to FIG. 5A, the doped region 108 is formed along the sidewalls of the OD region 202 within the channel region 100C. According to some embodiments, the doped region 108 covers only a first portion of the sidewall of the channel region 100C and leaves a second portion of the sidewall of the channel region 100C free of any doped region 108. The doped region 108 may be spaced apart from the source/drain region 204A or 204B by a distance L1, where the distance L1 is in a range greater than zero μm and less than about 0.5 μm. According to some embodiments, a length ratio of the doped region 108 to the length L_{D} as L_{X}/L_{D} is between about 40% and about 99%.

Referring to FIG. 5B, the doped region 108 is formed along the sidewalls of the OD region 202 across the channel region 100C and the source/drain region 204A or 204B. According to some embodiments, the doped region 108 covers or extends to only a first portion of the sidewall of the channel region 100C and leaves a second portion of the sidewall of the channel region 100C free of any doped region 108. The doped region 108 may extend in the channel region 100C by a length L2, where the length L2 is in a range greater than 0.03 μm and less than or equal to about L_{D}. According to some embodiments, a length ratio of the doped region 108 to the length L_{D} as L2/L_{D} is between about 3% and about 100%. Similarly, according to some embodiments, the doped region 108 covers only a third portion of the sidewall of the source/drain region 204A or 204B and leaves a fourth portion of the sidewall of the source/drain region 204A or 204B free of any doped region 108. The doped region 108 may extend in the source/drain region 204A or 204B by a length L3, where the length L3 is in a range greater than zero μm and less than about 1 μm. According to some embodiments, a length ratio of the length to the length L_{D} as L3/L_{D} is between about 0% and about 150%.

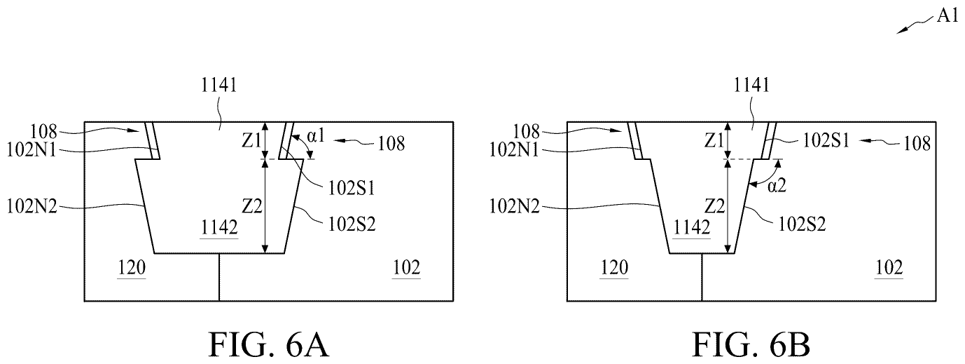

FIGS. 6A and 6B are enlarged cross-sectional views of a region A1 of the semiconductor device 100, in accordance with some embodiments of the present disclosure. Referring to FIG. 1J, the outer sidewall 102S or the inner sidewall 102N of the isolation structure 114 has a substantially straight sidewall. That means the first and second etching operations for forming the respective first trenches 102R1 and second trenches 102R2 have the same etching recipes or etching parameters. Therefore, the etching rate difference in the vertical direction and the horizontal direction may be substantially identical in the first and second etching operations, making the inner sidewall 102N1 and the outer sidewall 102S1 of the upper portion 1141 and those sidewalls 102N2, 102S2 of the lower portion 1142 the extend in similar slopes. In contrast, referring to FIG. 6A, the first etching operation and the second etching operation are performed using different etching recipes to adapt to different manufacturing flows or device requirements. As a result, the inner sidewall 102N1 and the 102N2 (or the outer sidewalls 102S1 and 102S2) are joined at a corner □ 1 formed between a slanted inner sidewall 102N1 (outer sidewall 102S1) of the upper portion 1141 and a horizontal surface at a top of the lower portion 1142. The lower portion 1142 has a width from a cross-sectional view at a top of the lower portion 1142 greater than a width at a bottom portion of the upper portion 1141. That means the isolation structure 114 extends in width at the interface of the upper portion 1141 and the lower portion 1142 when extending downward. According to some embodiments, the corner □ 1 has an included angle measured from the outer sidewall 102S1 of the upper portion 1141 to the horizontal surface of the top of the lower portion 1142. The angle of the corner □ 1 may be in a range of about 50 degrees to about 140 degrees. A recipe which causes the angle of the corner □ 1 to be less than about 50 degrees or greater than about 140 degrees may not lead to efficient etching operation in the vertical direction to form the first trench 102R1. According to some embodiments, both of the upper portion 1141 and the lower portion 1142 have a tapered width from their respective tops to their respective bottoms. According to some embodiments, the upper portion 1141 includes a height Z1 in a range of between about 5 nm (nanometer) and 500 nm. The height Z1 is adjusted according to the depth and area of the doped region 108 as desired. According to some embodiments, the lower portion 1142 has a height Z2. A height ratio Z1/Z2 of the upper portion 1141 to the lower portion 1142 may be in a range between about 5% and about 70%.

Referring to FIG. 6B, the first etching operation and the second etching operation are performed using different etching recipes to adapt to different manufacturing flows or device requirements. As a result, the inner sidewall 102N1 and the 102N2 (or the outer sidewalls 102S1 and 102S2) are joined at a corner □ 2 formed between a slanted inner sidewall 102N2 (outer sidewall 102S2) of the lower portion 1141 and a horizontal surface at a bottom of the upper portion 1141. The lower portion 1142 has a width from a cross-sectional view at a top of the lower portion 1142 less than a width at a bottom portion of the upper portion 1141. That means the isolation structure 114 reduces in width at the interface of the upper portion 1141 and the lower portion 1142 when extending downward. According to some embodiments, the corner □ 2 has an included angle measured from the outer sidewall 102S2 of the lower portion 1142 to the horizontal surface of the bottom of the upper portion 1141. The angle of the corner □ 2 may be in a range of about 80 degrees to about 160 degrees. A recipe which causes the angle of the corner □ 2 to be less than about 80 degrees or greater than about 160 degrees may not lead to efficient etching operation in the vertical direction to form the second trench 102R2. According to some embodiments, both of the upper portion 1141 and the lower portion 1142 have a tapered width from their respective tops to their respective bottoms.

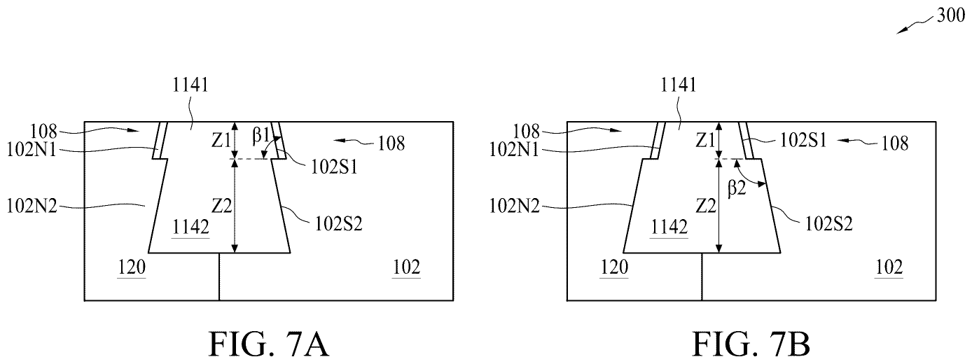

FIGS. 7A and 7B are enlarged cross-sectional views of the region A1 of the semiconductor device 100, in accordance with some embodiments of the present disclosure. Referring to FIG. 7A, the first etching operation and the second etching operation are performed using different etching recipes to adapt to different manufacturing flows or device requirements. As a result, the inner sidewall 102N1 and the 102N2 (or the outer sidewalls 102S1 and 102S2) are joined at a corner □□ formed between a slanted inner sidewall 102N1 (outer sidewall 102S1) of the upper portion 1141 and a horizontal surface at a bottom of the upper portion 1141. The lower portion 1142 has a width from a cross-sectional view at a top of the lower portion 1142 less than a width at a bottom portion of the upper portion 1141. That means the isolation structure 114 reduces in width at the interface of the upper portion 1141 and the lower portion 1142 when extending downward. According to some embodiments, the corner □□□ has an included angle measured from the outer sidewall 102S1 of the upper portion 1141 to the horizontal surface of the top of the lower portion 1142. The angle of the corner □□ may be in a range of about 80 degrees to about 160 degrees. A recipe which causes the angle of the corner □□□ to be less than about 80 degrees or greater than about 160 degrees may not lead to efficient etching operation in the vertical direction to form the first trench 102R1. According to some embodiments, both of the upper portion 1141 and the lower portion 1142 have a tapered width from their respective bottoms to their respective tops.

Referring to FIG. 7B, the first etching operation and the second etching operation are performed using different etching recipes to adapt to different manufacturing flows or device requirements. As a result, the inner sidewall 102N1 and the 102N2 (or the outer sidewalls 102S1 and 102S2) are joined at a corner □□ formed between a slanted inner sidewall 102N1 (outer sidewall 102S1) of the upper portion 1141 and a horizontal surface at a top of the lower portion 1142. The lower portion 1142 has a width from a cross-sectional view at a top of the lower portion 1142 greater than a width at a bottom portion of the upper portion 1141. That means the isolation structure 114 extends in width at the interface of the upper portion 1141 and the lower portion 1142 when extending downward. According to some embodiments, the corner □□ has an included angle measured from the outer sidewall 102S2 of the lower portion 1142 to the horizontal surface of the bottom of the upper portion 1141. The angle of the corner □□ may be in a range of about 50 degrees to about 140 degrees. A recipe which causes the angle of the corner □□ to be less than about 50 degrees or greater than about 140 degrees may not lead to efficient etching operation in the vertical direction to form the second trench 102R2. According to some embodiments, both of the upper portion 1141 and the lower portion 1142 have a tapered width from their respective bottoms to their respective tops.

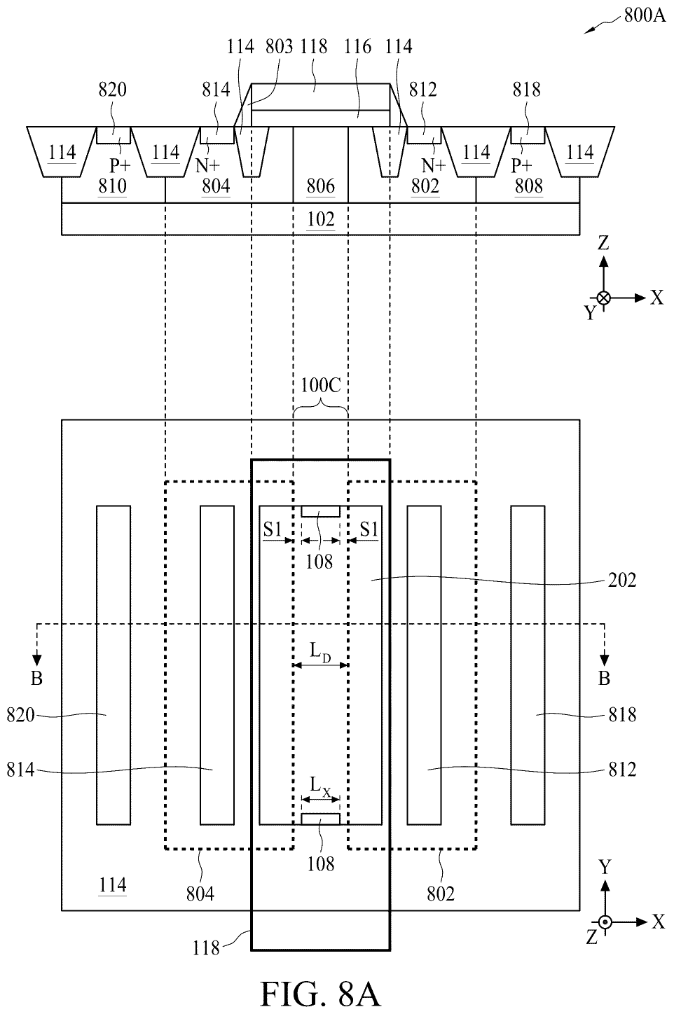

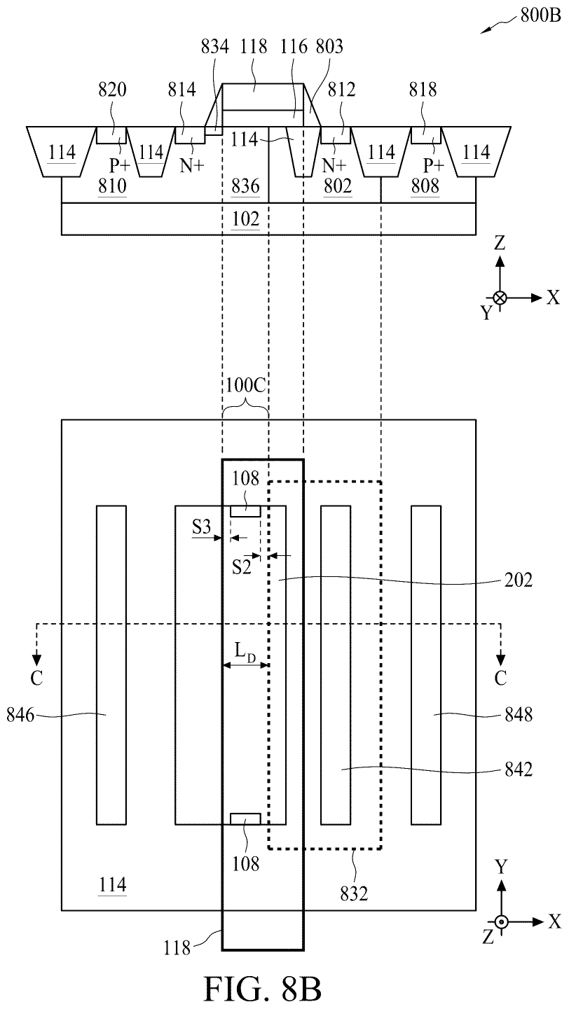

FIG. 8A shows a cross-sectional view and a top view of a semiconductor device 800A, in accordance with some embodiments of the present disclosure. The cross-sectional view is taken alone the sectional line BB in the top view. The semiconductor device 800A may be an HV FET device configured to operate under a relative high voltage, e.g., tens or hundreds of volts. According to some embodiments, the semiconductor device 800A is an N-type FET device. The semiconductor device 800A includes some features similar to those of the semiconductor device 100, and details of these similar features (share the same labels of those shown in FIGS. 1A to 1J) are not repeated for brevity. For example, the semiconductor device 800A includes the semiconductor substrate 102, the doped region 108, the isolation structures 114, the dielectric layer 116, the gate structure 118, and the OD region 202. Further, the semiconductor device 800A includes a pair of gate spacers 803 on two sides of the gate structure 118. The gate spacers 803 may be formed of a dielectric material, such as oxide, nitride, carbonitride, oxynitride, a combination thereof, or the like.

According to some embodiments, the semiconductor device 800A includes a pair of N-type source/drain regions 802, 804 arranged in the semiconductor substrate 102 on two sides of the gate spacers 803, a P-type channel region 806 arranged in the semiconductor substrate 102 between the source/drain regions 802, 804 below the dielectric layer 116. The area of the source/drain regions 802, 804 and the channel region 806 together constitute the OD region 202 of the semiconductor device 800A from a top-view perspective. Additionally, the semiconductor device 800A includes two P-type doped regions 808 and 810 on outer sides of the source/drain regions 802, 804. The P-type doped regions 808, 810 may serve as a guard ring or body contacts to ensure proper functioning of the semiconductor device 800A. According to some embodiments, the P-type doped regions 808, 810 may be joined to form a ring shape from a plan view. Since the source/drain regions 802, 804 and the two isolation structures 114 below the gate structure 118 are arranged in a symmetric manner on two sides of the channel region 806, the semiconductor device 800A is also referred to as a symmetric HV FET device.

According to some embodiments, the semiconductor device 800A further includes heavily doped regions 812, 814, 818 and 820 on the surface of the semiconductor substrate 102 in the respective source/drain regions 802, 804, and the doped regions 808, 810. The heavily doped regions 812, 814, 818 and 820 have dopant conductivity types the same as the respective source/drain regions 802, 804 and the doped regions 808, 810. The heavily doped regions 812, 814, 818 and 820 are formed to electrically connect the respective source/drain regions 802, 804, and the doped regions 808, 810 to overlying conductive vias or contacts. The heavily doped regions 812, 814, 818 and 820 may be in a strip or bar shape from a top-view perspective to facilitate their electrical interconnection with other conductive features. The heavily doped regions 812, 814, 818 and 820 are formed to include dopant concentrations greater than those of the respective source/drain regions 802, 804, and the doped regions 808, 810 to reduce the contact resistance.

The doped regions 108 are formed on the sidewalls of the channel region 806 between the source/drain regions 802 and 804. The doped regions 108 are formed on the sidewalls of the channel region 100C in the lengthwise direction (e.g., X-axis) of the channel region 100C from one of the source/drain regions 802 and 804 to the other of the source/drain regions 802 and 804. According to some embodiments, the length L_{X} of the doped region 108 measured in the lengthwise direction is substantially equal to or greater than about 0.01 μm. A length ratio of the length L_{X} to the channel length L_{D}, i.e., L_{X}/L_{D}, is between about 10% and about 100%. Furthermore, the doped region 108 is separated from the source/drain region 802 or 804 by a distance S1. The distance S1 may be in a range greater than about 0.02 μm. A dimension ratio of the distance S1 to the channel length L_{D}, i.e., S1/L_{D}, is between about 5% and about 48%.

FIG. 8B shows a cross-sectional view and a top view of a semiconductor device 800B, in accordance with some embodiments of the present disclosure. The cross-sectional view is taken alone the sectional line CC in the top view. The semiconductor device 800B may be an HV FET device configured to operate under a relative high voltage, e.g., tens or hundreds of volts. According to some embodiments, the semiconductor device 800B is an N-type FET device. The semiconductor device 800B includes some features similar to those of the semiconductor device 100 and 800A, and details of these similar features (share the same labels of those shown in FIGS. 1A to 1J) are not repeated for brevity. For example, the semiconductor device 800A includes the semiconductor substrate 102, the doped region 108, the isolation structures 114, the dielectric layer 116, the gate structure 118, the OD region 202, and the gate spacers 803. Further, the semiconductor device 800B is similar to the semiconductor device 800A in that both of them include the features of the drain region 802, the doped region 808, and the heavily doped regions 812, 814, 818 and 820. The main difference between the semiconductor device 800B and the semiconductor device 800A is that the semiconductor device 800B includes an asymmetric source/drain arrangement. Referring to FIG. 8A and FIG. 8B, the source/drain region 804, which is symmetric to the drain region 802, and the channel region 806 that are formed in the semiconductor device 800A are replaced with a source LDD region 834 and a channel region 836. According to some embodiments, the drain current flows from the drain region 802 to the source LDD region 834 through the channel region 836. The source LDD region 834 has an area in the cross-sectional view less than that of the drain region 802 in the cross-sectional view, and thus the drain region 802 and the source LDD region 834 are asymmetric to the channel region 836. Moreover, the channel region 836 is merged with the doped region 810, and the channel region 836 and the doped region 810 can be seen as a merged doped region 810. Further, in adaption to the merged doped region 810, the isolation structure 114 arranged within the source/drain region 804 is removed from the semiconductor device 800B, and therefore the asymmetric semiconductor device 800B is formed.

The doped regions 108 are formed on the sidewalls of the channel region 836 between the drain region 802 and the source LDD region 834. The doped regions 108 are formed on the sidewalls of the channel region 100C in the lengthwise direction (e.g., X-axis) of the channel region 100C from one of the source/drain regions 802 and 834 to the other of the source/drain regions 802 and 834. According to some embodiments, the length L_{X} of the doped region 108 measured in the lengthwise direction is between about 0.01 μm and 0.05 μm, such as 0.03 μm. A length ratio of the length L_{X} to the channel length L_{D}, i.e., L_{X}/L_{D}, is between about 10% and about 100%. Furthermore, the doped region 108 is separated from the source/drain region 802 by a distance S2. The distance S2 may be in a range greater than zero μm and less than about 0.02 μm. A dimension ratio of the distance S2 to the channel length L_{D}, i.e., S2/L_{D}, is between about 0% and about 30%. Similarly, the doped region 108 is separated from the source/drain region 834 by a distance S3. The distance S3 may be in a range greater than zero μm and less than about 0.03 μm. A dimension ratio of the distance S2 to the channel length L_{D}, i.e., S2/L_{D}, is between about 0% and about 45%.

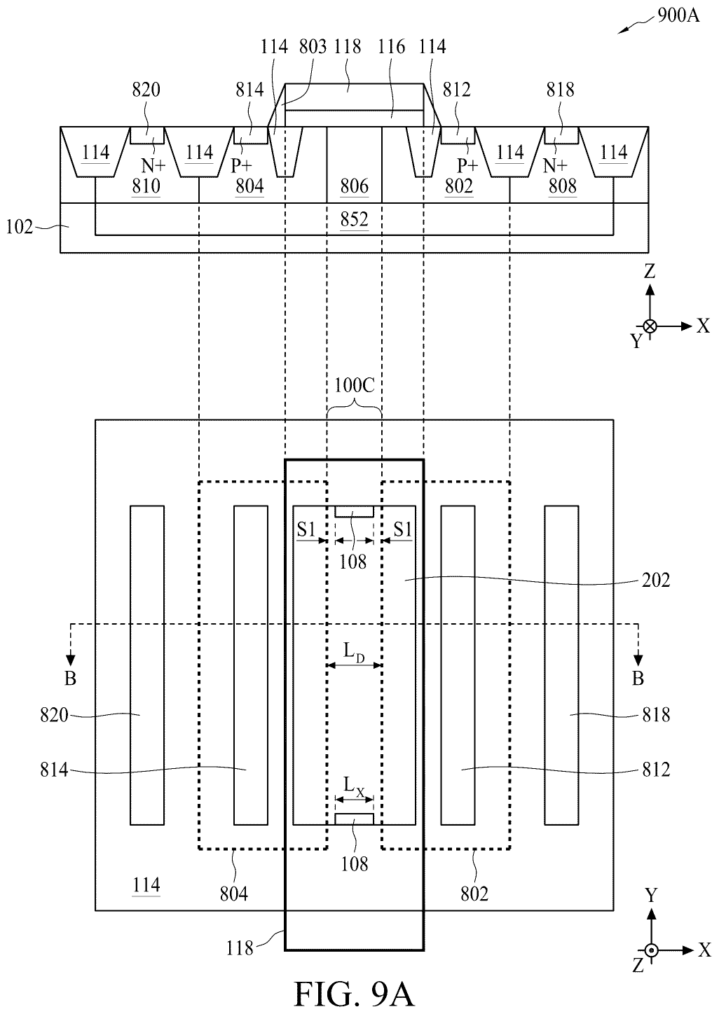

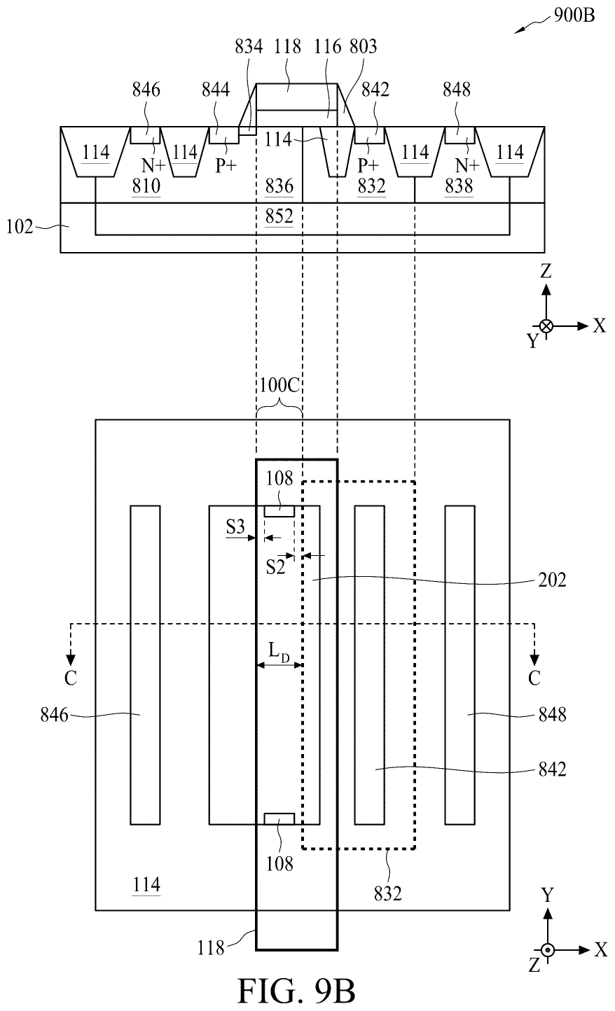

FIG. 9A shows a cross-sectional view and a top view of a semiconductor device 900A, in accordance with some embodiments of the present disclosure. FIG. 9B shows a cross-sectional view and a top view of a semiconductor device 900B, in accordance with some embodiments of the present disclosure. The semiconductor devices 900A and 900B may be HV FET devices. According to some embodiments, the semiconductor devices 900A and 900B are P-type FET devices. The semiconductor devices 900A and 900B are dual devices of the semiconductor devices 800A and 800B, respectively. The difference between the semiconductor device 800A (800B) and the semiconductor device 900A (900B) lies only in that the dopant conductivity types of the doped regions in the features of the semiconductor device 800A (800B) are opposite to those of the doped regions in the same features of the semiconductor device 900A (900B). For example, the source/drain regions 802, 804 and 834 are P-type source/drain regions in the semiconductor devices 900A and 900B, and the channel regions 806, 836 and the doped regions 808, 810 are N-type doped regions in the semiconductor devices 900A and 900B. Similarly, the doped regions 108 are N-type doped regions in the semiconductor devices 900A and 900B. Further, the semiconductor devices 900A and 900B includes an additional N-type deep well region 852 in the semiconductor substrate 102 below the aforementioned source/drain regions and doped regions.

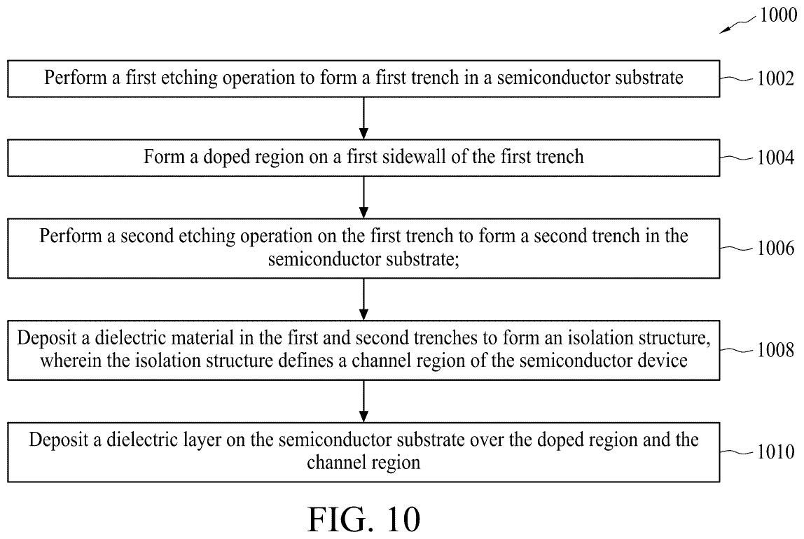

FIG. 10 shows a schematic flow chart of a method of manufacturing a semiconductor device, in accordance with some embodiments of the present disclosure. It shall be understood that additional steps can be provided before, during, and after the steps in method 1000, and some of the steps described below can be replaced with other embodiments or eliminated. The order of the steps shown in FIG. 10 may be interchangeable. Some of the steps may be performed concurrently or independently.

At step 1002, a first etching operation is performed to form a first trench in a semiconductor substrate.

At step 1004, a doped region is formed on a first sidewall of the first trench.

At step 1006, a second etching operation is performed on the first trench to form a second trench in the semiconductor substrate.

At step 1008, a dielectric material is deposited in the first and second trenches to form an isolation structure, wherein the isolation structure defines a channel region of the semiconductor device.

At step 1010, a dielectric layer is deposited on the semiconductor substrate over the doped region and the channel region.

In accordance with one embodiment of the present disclosure, a method of manufacturing a semiconductor device includes: performing a first etching operation to form a first trench in a semiconductor substrate; forming a doped region to on a first sidewall of the first trench; performing a second etching operation on the first trench to form a second trench in the semiconductor substrate; depositing a dielectric material in the first and second trenches to form an isolation structure, wherein the isolation structure defines a channel region of the semiconductor device from a top-view perspective; and depositing a dielectric layer on the semiconductor substrate over the doped region and the channel region.

In accordance with one embodiment of the present disclosure, a method of manufacturing a semiconductor device includes: performing a first etching operation to form a first trench in a semiconductor substrate; forming a doped region on a sidewall of the first trench; performing a second etching operation on the first trench to form a second trench in the semiconductor substrate; forming an isolation structure in the first and second trenches to define an oxide definition (OD) region of the semiconductor device from a top-view perspective, wherein the doped region is arranged on a sidewall of the OD region; and depositing a dielectric layer on the semiconductor substrate, wherein the dielectric layer has a first thickness in a central region over the OD region and a second thickness, less than the first thickness, aligned with the doped region.

In accordance with one embodiment of the present disclosure, a semiconductor device includes: a first isolation structure in a semiconductor substrate; a second isolation structure adjacent to the first isolation structure in the semiconductor substrate, wherein the first isolation structure and the second isolation structure define boundaries of a channel region of the semiconductor device; a gate dielectric layer on the semiconductor substrate between the first isolation structure and the second isolation structure; a gate structure over the gate dielectric layer; and a first doped region arranged on a first sidewall of the channel region in the semiconductor substrate, the first sidewall facing the first or second isolation structure.

The foregoing outlines structure of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
performing a first etching operation to form a first trench in a semiconductor substrate;
forming a doped region to on a first sidewall of the first trench;
performing a second etching operation on the first trench to form a second trench in the semiconductor substrate;
depositing a dielectric material in the first and second trenches to form an isolation structure, wherein the isolation structure defines a channel region of the semiconductor device from a top-view perspective; and
depositing a dielectric layer on the semiconductor substrate over the doped region and the channel region.

2. The method of claim 1, wherein the first trench includes a first inner sidewall and a first outer sidewall, and the first inner sidewall is closer to the channel region than the first outer sidewall is, wherein the first sidewall is the first inner sidewall of the first trench.

3. The method of claim 2, wherein the first trench further comprises a second inner sidewall on a side of the channel region opposite to the first inner sidewall, comprising forming the doped region on the second inner sidewall.

4. The method of claim 2, further comprising forming the doped region on a perimeter, including the first inner sidewall, of the first trench.

5. The method of claim 2, further comprising forming a patterned mask layer on the semiconductor substrate, wherein the patterned mask layer includes a portion covers the first outer sidewall and exposes the first inner sidewall of the first trench.

6. The method of claim 5, wherein the dielectric layer comprises a central region having a substantially uniform thickness across and an edge region having a non-uniform thickness.

7. The method of claim 6, wherein the edge region is vertically aligned with the doped region from a cross-sectional view.

8. The method of claim 1, further comprising forming a gate structure on the dielectric layer, wherein the gate structure at least partially overlaps the doped region from a top-view perspective.

9. The method of claim 8, wherein the gate structure overlaps an entirety of the doped region from a top-view perspective.

10. The method of claim 1, wherein the forming of the doped region comprising using thermal oxidation on the semiconductor substrate.

11. A method of manufacturing a semiconductor device, comprising:
performing a first etching operation to form a first trench in a semiconductor substrate;
forming a doped region on a sidewall of the first trench;
performing a second etching operation on the first trench to form a second trench in the semiconductor substrate;
forming an isolation structure in the first and second trenches to define an oxide definition (OD) region of the semiconductor device from a top-view perspective, wherein the doped region is arranged on a sidewall of the OD region; and
depositing a dielectric layer on the semiconductor substrate, wherein the dielectric layer has a first thickness in a central region over the OD region and a second thickness, less than the first thickness, aligned with the doped region.

12. The method of claim 11, wherein the forming the doped region on the sidewall of the first trench comprises forming the doped region on an inner sidewall of the first trench while keeping an outer sidewall of the first trench free of the doped region.

13. The method of claim 11, further comprising forming source/drain regions on two sides of the OD region, wherein the doped region includes a portion extended to the source/drain regions from a top-view perspective.

14. The method of claim 11, wherein the doped region has a bottom higher than a bottom surface of the isolation structure.

15. The method of claim 11, wherein the doped region covers a portion of a bottom surface of the isolation structure.

16. The method of claim 11, wherein the isolation structure has an upper portion and a lower portion below the upper portion, wherein the upper portion includes a bottom with a first width different from a second width of a top of the lower portion.

17. The method of claim 16, wherein each of the upper portion and the lower portion has a tapered width from their respective bottoms to their respective top.

18. A semiconductor device, comprising:
a first isolation structure in a semiconductor substrate;
a second isolation structure adjacent to the first isolation structure in the semiconductor substrate, wherein the first isolation structure and the second isolation structure define boundaries of a channel region of the semiconductor device;
a gate dielectric layer on the semiconductor substrate between the first isolation structure and the second isolation structure;
a gate structure over the gate dielectric layer; and
a first doped region arranged on a first sidewall of the channel region in the semiconductor substrate, the first sidewall facing the first or second isolation structure.

19. The semiconductor device of claim 18, further comprising a second doped region arranged on a second sidewall of the channel region opposite to the first sidewall in the semiconductor substrate.

20. The semiconductor device of claim 18, wherein the first doped region at least partially overlaps the gate structure from a top-view perspective.
